(19) United States
(12) Patent Application Publication
(10) Pub. No.: US 2019/0267421 A1
(43) Pub. Date: Aug. 29, 2019

(54) IMAGE CAPTURING DEVICE

(71) Applicant: CANON KABUSHIKI KAISHA, Tokyo (JP)

(72) Inventors: Sho Suzuki, Machida-shi (JP); Mitsuhiro Yomori, Tama-shi (JP); Takehito Okabe, Yokohama-shi (JP); Takashi Okagawa, Sagamihara-shi (JP)

(21) Appl. No.: 16/278,832

(22) Filed: Feb. 19, 2019

(30) Foreign Application Priority Data
Feb. 27, 2018 (JP) 2018-033678

(51) Int. Cl. H01L 27/146

(52) U.S. Cl. CPC H01L 27/14625; H01L 27/14623; H01L 27/14685; G05D 1/0246; H01L 27/14627; H01L 27/14621; H01L 27/14643; H01L 27/14603

(57) ABSTRACT

Image capturing device includes semiconductor substrate having photoelectric converters in light-receiving area and light-shielded area, insulating film arranged above principal face of the substrate and having holes arranged above the photoelectric converters, waveguide portions arranged in the holes, connecting portion connecting the waveguide portions above the insulating film, light-shielding film arranged on the connecting portion having opening in the light-receiving area, SiN film arranged on the light-shielding film so that the opening is arranged between the SiN film and the substrate in the light-receiving area, and insulator film having portion located in the opening and having portion located between the light-shielding film and the SiN film. Distance between upper face of the light-shielding film and the principal face is smaller than distance between lower face of the SiN film and the principal face.

### BACKGROUND OF THE INVENTION

### Field of the Invention

The present invention relates to an image capturing device.

### Description of the Related Art

There is known an image capturing device including a waveguide to increase an amount of light entering a photoelectric converter. An image capturing device described in FIG. 7 (Example 3) of Japanese Patent Laid-Open No. 2014-36037 includes an insulator having a plurality of holes arranged above a plurality of light-receiving portions arranged in a semiconductor substrate and a plurality of waveguide portions arranged in the plurality of holes, respectively. The plurality of waveguide portions are connected by a connecting portion on the insulator. A light-shielding portion is arranged on the connecting portion and covered with a silicon oxide film forming a second member having a flat upper face. A silicon nitride film forming a fourth member and a first lens is arranged on the second member. The silicon nitride film is covered with a planarized film. Note that an OB pixel area is not explicitly indicated in FIG. 7 (Example 3) of Japanese Patent Laid-Open No. 2014-36037.

FIG. 10 (Example 1) of Japanese Patent Laid-Open No. 2014-36037 describes an image capturing device in which a silicon oxide film serving as a second member is arranged so as to cover a connecting portion in a pixel area and an OB pixel area. A silicon nitride film forming a first lens and a fourth member is arranged above a second member in a pixel area, and a light-shielding film is arranged above the second member in an OB pixel area.

In FIG. 7 (Example 3) of Japanese Patent Laid-Open No. 2014-36037, although the OB pixel area is not explicitly indicated, the first lens can be arranged above the upper face of the second member in the pixel area, and the light-shielding film can be arranged above the second member in the OB pixel area as in Example 1. If such an arrangement is assumed, light propagating through the silicon nitride film forming the fourth member in the pixel area enters under the light-shielding film in the OB pixel area and further enters the light-receiving portion of the OB pixel area through the connecting portion. Accordingly, the OB level (black reference level) can become unstable.

### SUMMARY OF THE INVENTION

The present invention provides an image capturing device having a structure advantageous in suppressing light incidence to a light-shielding pixel.

One of aspects of the present invention provides an image capturing device having a light-receiving area and a light-shielded area, comprising: a semiconductor substrate in which a plurality of photoelectric converters in the light-receiving area and the light-shielded area are arranged; an insulating film arranged above a principal face of the semiconductor substrate and having a plurality of holes arranged above the plurality of photoelectric converters; a plurality of waveguide portions arranged in the plurality of holes, respectively; a connecting portion configured to connect the plurality of waveguide portions above the insulating film; a light-shielding film arranged on the connecting portion in the light-receiving area and the light-shielded area and having an opening in the light-receiving area; a silicon nitride film arranged on the light-shielding film in the light-receiving area and the light-shielded area so that the opening is arranged between the silicon nitride film and the semiconductor substrate in the light-receiving area; and an insulator film having a portion located in the opening in the light-receiving area and having a portion located between the light-shielding film and the silicon nitride film in the light-receiving area and the light-shielded area, wherein in the light-receiving area and the light-shielded area, a distance between an upper face of the light-shielding film and the principal face is smaller than a distance between a lower face of the silicon nitride film and the principal face.

Further features of the present invention will become apparent from the following description of exemplary embodiments with reference to the attached drawings.

### BRIEF DESCRIPTION OF THE DRAWINGS

FIG. 1 is a plan view of an image capturing device according to the first embodiment of the present invention;

FIG. 2 is a schematic sectional view showing the arrangement of the image capturing device according to the first embodiment of the present invention;

FIG. 3 shows schematic sectional views showing the arrangement of the image capturing device according to the first embodiment of the present invention;

FIG. 4 is a sectional view showing an example of a method of manufacturing the image capturing device according to the first embodiment of the present invention;

FIG. 5 is a sectional view showing an example of the method of manufacturing the image capturing device according to the first embodiment of the present invention;

FIG. 6 is a sectional view showing an example of the method of manufacturing the image capturing device according to the first embodiment of the present invention;

FIG. 7 is a sectional view showing an example of the method of manufacturing the image capturing device according to the first embodiment of the present invention;

FIG. 8 is a sectional view showing an example of the method of manufacturing the image capturing device according to the first embodiment of the present invention;

FIG. 9 is a sectional view showing an example of the method of manufacturing the image capturing device according to the first embodiment of the present invention;

FIG. 10 is a sectional view showing an example of a method of manufacturing the image capturing device according to the second embodiment of the present invention;

FIG. 11 is a sectional view showing an example of the method of manufacturing the image capturing device according to the second embodiment of the present invention;

FIG. 12 is a block diagram showing an example of an apparatus mounted with the image capturing device; and

FIG. 13A shows views of the apparatus mounted with the image capturing device, and FIG. 13B is a block diagram of the apparatus.

### DESCRIPTION OF THE EMBODIMENTS

The present invention will be described by way of its exemplary embodiments with reference to the accompanying drawings. In this specification, the first conductivity type and the second conductivity type are expressions to distinguish the conductivity types from each other. If the first conductivity type is a p-type, the second conductivity type is an n-type, and vice versa. In this specification, a film which is explained as being arranged on another film can be include a film arranged above another film via a still another film. In this specification, a film which is explained as being arranged above another film can be include a film arranged above another film so as to contact with the another film.

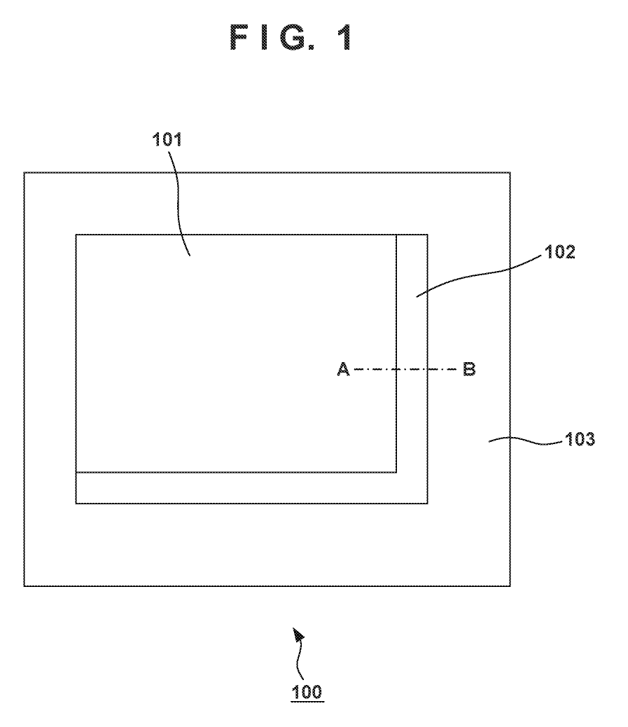

FIG. 1 is a plan view of an image capturing device 100 according to the first embodiment of the present invention. The image capturing device 100 can be arranged as a CMOS image sensor. The image capturing device 100 can include a light-receiving area 101, a light-shielded area (OB pixel area) 102, and a peripheral circuit area 103. A plurality of pixels are arranged in the light-receiving area 101, and each pixel includes a photoelectric converter. Each pixel in the light-receiving area 101 can be used as an effective pixel. A plurality of pixels are arranged in the light-shielded area 102, and each pixel includes a photoelectric converter. The photoelectric converters of the plurality of pixels arranged in the light-shielded area 102 are shielded with a light-shielding film, and these pixels can be used as black reference pixels (optical black pixels). Peripheral circuits for reading out signals from the plurality of pixels of the light-receiving area 101 and the plurality of pixels of the light-shielded area 102 are arranged in the peripheral circuit area 103. The peripheral circuits can include, for example, a vertical scanning circuit, column circuits (a plurality of column readout circuits), a horizontal scanning circuit, and a timing generator.

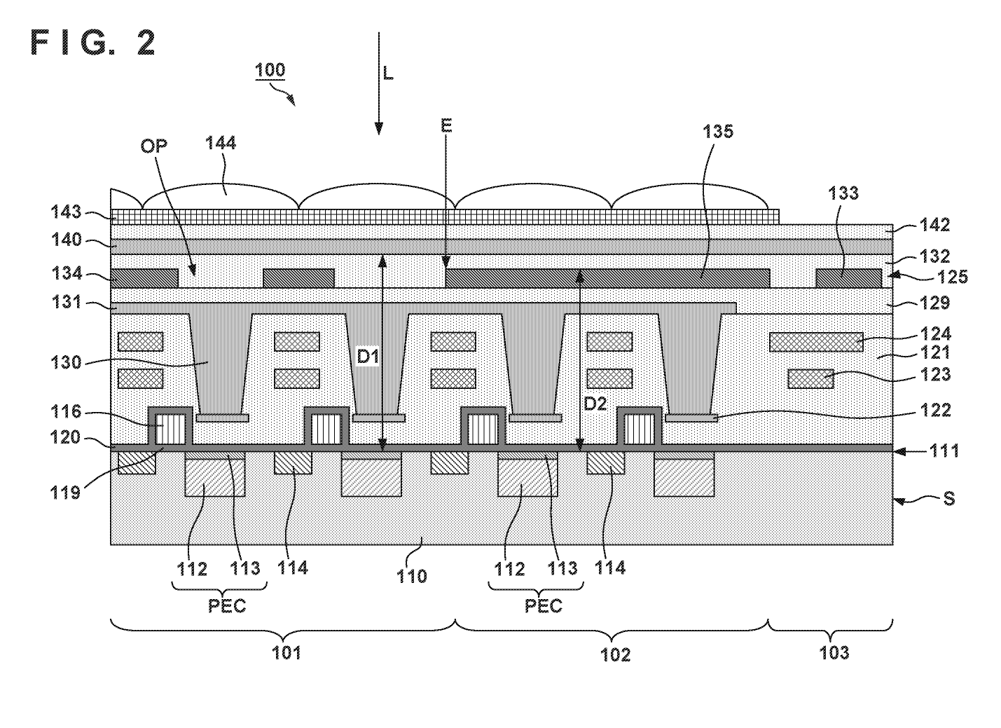

FIG. 2 is a schematic sectional view along a line A-B in the image capturing device 100 of FIG. 1. The image capturing device 100 includes a semiconductor substrate S including a semiconductor layer 110. The semiconductor substrate S is, for example, a silicon substrate. The semiconductor layer 110 is, for example, a semiconductor layer of a first conductivity type and can be formed on a semiconductor material (not shown) by epitaxial growth. The semiconductor substrate S has a principal face 111. The principal face 111 can include, for example, the upper face of the semiconductor layer 110. The principal face 111 of the semiconductor substrate S is an interface between the semiconductor substrate S and a gate insulating film 119 arranged on the semiconductor substrate S. Light enters the interior of the semiconductor layer 110 or the semiconductor substrate S via the principal face 111.

A plurality of photoelectric converters PEC of the light-receiving area 101 and a plurality of photoelectric converters PEC of the light-shielded area 102 are arranged in the semiconductor layer 110. Each of the plurality of photoelectric converters PEC of the light-receiving area 101 and the plurality of photoelectric converters PEC of the light-shielded area 102 can include a semiconductor region 112 of a second conductivity type and a semiconductor region 113 of the first conductivity type between the semiconductor region 112 and the principal face 111 so as to contact the semiconductor region 112. Each semiconductor region 112 of the second conductivity type and each semiconductor region 113 of the first conductivity type form a p-n junction. Each semiconductor region 112 of the second conductivity type and the semiconductor layer 110 of the first conductivity type form a p-n junction. In addition, a plurality of semiconductor regions 114 of the second conductivity type are arranged in the semiconductor layer 110. The plurality of semiconductor regions 114 form a floating diffusion (charge-voltage converter).

Each semiconductor region 112 of the second conductivity type forms a charge accumulation region and accumulates the charge generated by photoelectric conversion. The charge accumulated in the semiconductor region 112 is transferred to each semiconductor region 114 via a channel formed between each semiconductor region 112 and the corresponding semiconductor regions 114 by applying an active voltage to a corresponding gate electrode 116. Each gate electrode 116 is arranged above the principal face 111 via the corresponding gate insulating film 119 and forms a transfer gate. Each semiconductor region 114 converts the transferred charge into a voltage, and this voltage can be applied to the gate electrode of an amplification transistor (not shown). The amplification transistor can be arranged so as to output, to a column signal line, a signal corresponding to the voltage applied to its gate electrode.

An insulating film 120 can be arranged on the principal face 111 of the semiconductor substrate S. The insulating film 120 can be arranged to cover each gate electrode 116. The insulating film 120 can be made of silicon nitride. The refractive index of the insulating film 120 can fall within the range of, for example, 1.40 to 1.60. A plurality of wiring layers (electrically-conductive member layers) such as a first wiring layer 123, a second wiring layer 124, and a third wiring layer 125 can be arranged above the principal face 111 of the semiconductor substrate S. An interlayer insulating film 121 and an interlayer insulating film 129 can be arranged above the principal face 111 of the semiconductor substrate S so as to electrically insulate the first wiring layer 123, the second wiring layer 124, and the third wiring layer 125 from each other. Each interlayer insulating film 121 is a multilayer film including a plurality of interlayer insulating layers positioned between the two wiring layers. In the following description, a film may be a monolayer film or multilayer film. The interlayer insulating film 129 insulates the second wiring layer 124 from the third wiring layer 125. The interlayer insulating film 121 and the interlayer insulating film 129 can be made of silicon oxide.

The first wiring layer 123, the second wiring layer 124, and the third wiring layer 125 have different levels with respect to the principal face 111 of the semiconductor substrate S. As an example, the electrically-conductive members of the first wiring layer 123 and the second wiring layer 124 can be made of copper, and the electrically-conductive member of the third wiring layer 125 can be made of aluminum. As an example, the third wiring layer 125 can include a light-shielding film 134 arranged in the light-receiving area 101, a light-shielding film 135 arranged in the light-shielded area 102, and an electrically-conductive member 133 arranged in the peripheral circuit area 103. In other words, the light-shielding film 134, the light-shielding film 135, and the electrically-conductive member 133 can be arranged in the third wiring layer 125 as the single layer. The material of the electrically-conductive members of the first wiring layer 123, the second wiring layer 124, and the third wiring layer 125 is not limited to the examples described above, but can be made of another electrically-conductive member. The third wiring layer 125 can include another electrically-conductive member such as an electrode pad.

The electrically-conductive member of the first wiring layer 123 and the electrically-conductive member of the second wiring layer 124 are electrically connected by a plug (not shown). Except a portion electrically connected by this plug, the electrically-conductive member of the first wiring layer 123 and the electrically-conductive member of the second wiring layer 124 are electrically insulated from each other by the interlayer insulating film 121. The electrically-conductive member of the second wiring layer 124 and the electrically-conductive member 133 of the third wiring layer 125 are electrically connected by a plug (not shown). Except a portion electrically connected by this plug, the electrically-conductive member of the second wiring layer 124 and the electrically-conductive member 133 of the third wiring layer 125 are electrically insulated from each other by the interlayer insulating film 121 and the interlayer insulating film 129.

The interlayer insulating film 121 has a plurality of holes arranged above the plurality of photoelectric converters PEC of the light-receiving area 101 and the plurality of photoelectric converters PEC of the light-shielded area 102. A plurality of waveguide portions 130 are arranged in the plurality of holes, respectively. The plurality of waveguide portions 130 include the waveguide portions 130 between the photoelectric converters PEC of the light-shielded area 102 and the light-shielding film 135. The plurality of waveguide portions 130 can be made of silicon nitride. The refractive index of the plurality of waveguide portions 130 is higher than the refractive index of the interlayer insulating film 121 and is, for example, 1.60 or more and preferably falls within the range of 1.80 to 2.40.

A connecting portion 131 for connecting the plurality of waveguide portions 130 is arranged on the interlayer insulating film 121. The connecting portion 131 connects the plurality of waveguide portions 130 on the interlayer insulating film 121. The connecting portion 131 can be made of the same material as that of the plurality of waveguide portions 130. The connecting portion 131 can overlap the light-shielding film 134 in the light-receiving area 101. The connecting portion 131 can overlap the light-shielding film 135 in the light-shielded area 102. The connecting portion 131 can be made of silicon nitride. The connecting portion 131 can include a portion for connecting the plurality of waveguide portions 130 in the light-receiving area 101 and a portion for connecting the plurality of waveguide portions in the light-shielded area 102. The connecting portion 131 may extend from the light-shielded area 102 to the peripheral circuit area 103 or may not exit in the peripheral circuit area 103.

The light-shielding film 134 is arranged in the light-receiving area 101 such that separated light beams respectively enter the plurality of photoelectric converters PEC of the light-receiving area 101. In other words, the light-shielding film 134 is arranged such that a light beam passing through one microlens 144 enters one photoelectric converter PEC. The light-shielding film 134 can have a plurality of openings OP respectively corresponding to the plurality of photoelectric converters PEC of the light-receiving area 101. Each photoelectric converter PEC of the light-receiving area 101 has an arrangement so as to receive light entering through the corresponding opening OP. Alternatively, the light-shielding film 134 has, for example, a grating shape. The light-shielding film 134 can be made of a metal material such as aluminum.

The light-shielding film 135 is arranged in the light-shielded area 102. The light-shielding film 135 can be arranged so as to cover all the plurality of photoelectric converters PEC of the light-shielded area 102. The light-shielding film 135 can be arranged so as not to have an opening in the light-shielded area 102. The light-shielding film 135 can be made of the same material as that of the light-shielding film 134, but may be made of a material different from that of the light-shielding film 134. The light-shielding films 134 and 135 can be arranged above the connecting portion 131 via the interlayer insulating film 129. The upper face of the interlayer insulating film 129 is flatter than the lower face of the interlayer insulating film 129 in an area including the light-receiving area 101 and the light-shielded area 102. Alternatively, the interlayer insulating film 129 can have a flat upper face in the entire area including the light-receiving area 101 and the light-shielded area 102. The light-shielding films 134 and 135 and the electrically-conductive member 133 can be arranged along the flat upper face. Note that the light-shielding films 134 and 135 may be arranged to contact the connecting portion 131. An end portion E of the light-shielding film 135 (a portion arranged in the light-shielded area 102 out of the light-shielding films 134 and 135) on the side of the light-receiving area 101 can overlap at least one of some of the plurality of waveguide portions 130 and the connecting portion 131 in the orthographic projection (planar view) to the principal face 111.

An insulator film 132 can be arranged in the openings OP (openings formed in the light-shielding films 134 and 135 and the electrically-conductive member forming the electrically-conductive member 133) formed in the light-shielding film 134. The insulator film 132 can be made of silicon oxide. The insulator film 132 can be arranged so as to cover the light-shielding films 134 and 135 and the electrically-conductive member 133. The upper face of the insulator film 132 can be flatter than the lower face of the insulator film 132. Alternatively, the insulator film 132 can have a flat upper face. Such a flat upper face of the insulator film 132 can be formed so as to spread over the entire area including the light-receiving area 101 and the light-shielded area 102. The insulator film 132 has a portion positioned in the openings OP in the light-receiving area 101. In addition, the insulator film 132 has a portion positioned between the light-shielding film 135 and a light transmissive film 140 in the light-receiving area 101 and the light-shielded area 102.

The light transmissive film 140 can be arranged above the light-shielding films 134 and 135, the electrically-conductive member 133, and the insulator film 132. The light transmissive film 140 can be arranged on the flat upper face of the insulator film 132. The light transmissive film 140 can have a refractive index higher than that of the insulator film 132. The light transmissive film 140 can function as a protective film. The light transmissive film 140 can be made of silicon nitride. Silicon nitride is a material containing nitrogen and silicon. Silicon nitride may also contain another element such as oxygen.

An organic material film 142 can be arranged on the light transmissive film 140. The organic material film 142 can have a refractive index lower than that of the light transmissive film 140. The organic material film 142 can be made of silicon oxide. A color filter 143 and microlenses 144 can be arranged on the organic material film 142.

In the light-receiving area 101 and the light-shielded area 102, a distance D2 between the principal face 111 and the upper face of the light-shielding films 134 and 135 is smaller than a distance D1 between the lower face of the light transmissive film 140 and the principal face 111 of the semiconductor substrate S. The distance D2 of this arrangement is smaller than that of an arrangement in which light-shielding films 134 and 135 are arranged above the light transmissive film 140. Accordingly, this arrangement is advantageous in reducing light entering the connecting portion 131 in the light-shielded area 102 near the boundary between the light-receiving area 101 and the light-shielded area 102. This makes it possible to suppress the occurrence of photoelectric conversion in the photoelectric converters PEC of the light-shielding pixels by light entering the connecting portion 131 in the light-shielded area 102, in other words, to suppress variations in outputs from the light-shielding pixels. Since the connecting portion 131 can function as a core portion for propagating the light, if light enters the connecting portion 131 in the light-shielded area 102, the light propagates through the connecting portion 131 and enters the photoelectric converters PEC of the light-shielding pixels via the waveguide portions 130. In addition, the above arrangement is also advantageous in reducing the crosstalk (for example, color mixing) between the photoelectric converters PEC (between the pixels) in the light-receiving area 101.

The upper face of each of the plurality of waveguide portions 130 and the upper face of the connecting portion 131 can form a flat upper face continuously spreading in the entire area including the light-receiving area 101 and the light-shielded area 102. This arrangement is advantageous in flattening of the faces on which the light-shielding films 134 and 135 and the electrically-conductive member 133 are arranged (for example, thinning of the interlayer insulating film 129). This arrangement is also advantageous in that the positions of the light-shielding films 134 and 135 and the electrically-conductive member 133 come close to the principal face 111. The connecting portion 131 can be arranged not to have an opening in the entire area including the light-receiving area 101 and the light-shielded area 102. This arrangement is also advantageous in that the positions of the light-shielding films 134 and 135 and the electrically-conductive member 133 come close to the principal face 111. The arrangement in which the positions of the light-shielding films 134 and 135 and the electrically-conductive member 133 come close to the principal face 111 means that the distance D2 is reduced. This makes it possible to suppress variations in outputs from the light-shielding pixels, and advantageous to reduce the crosstalk (for example, color mixing) between the photoelectric converters PEC (between the pixels) in the light-receiving area 101.

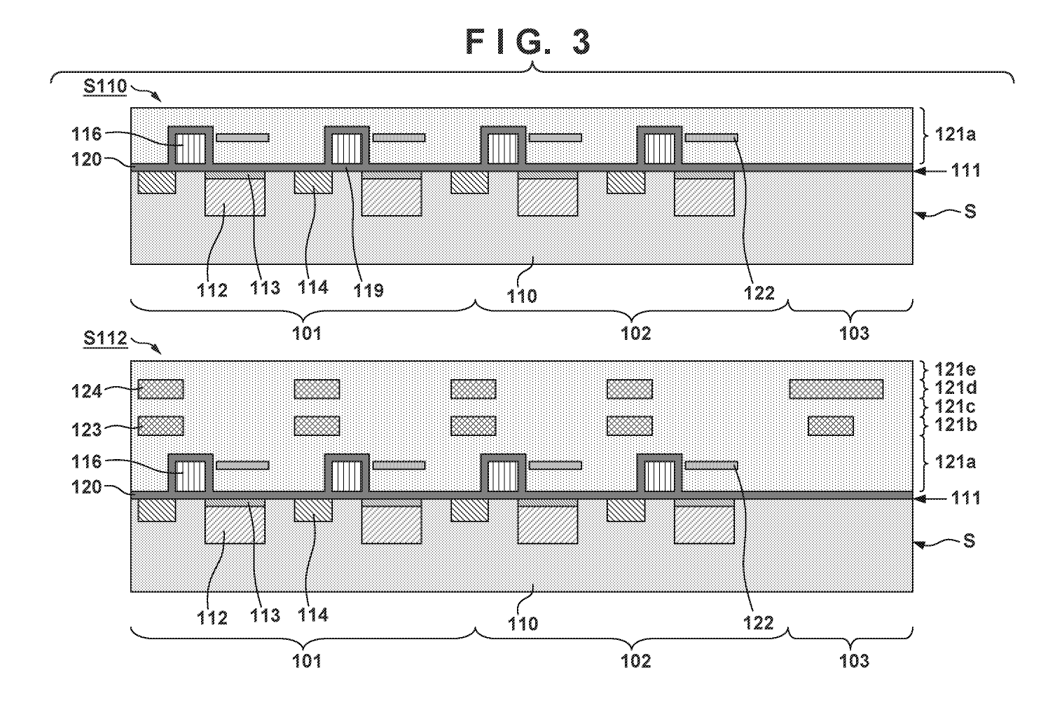

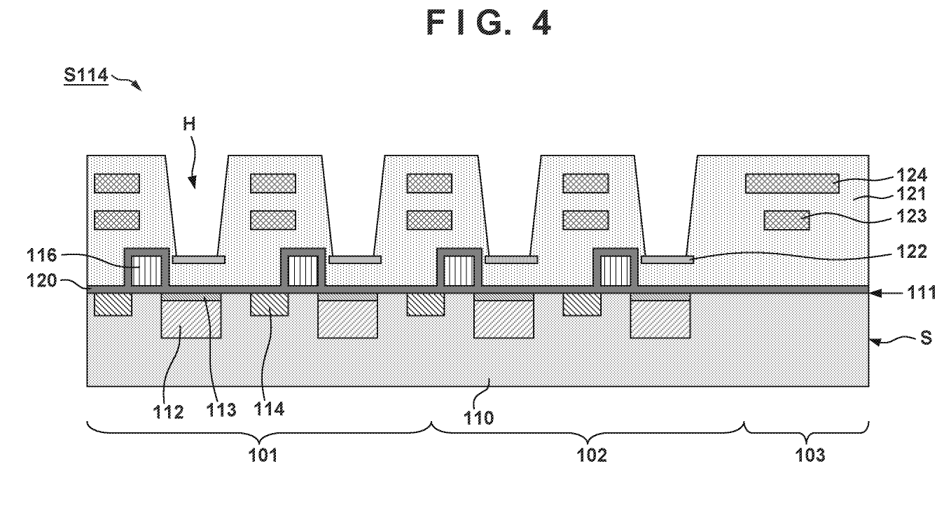

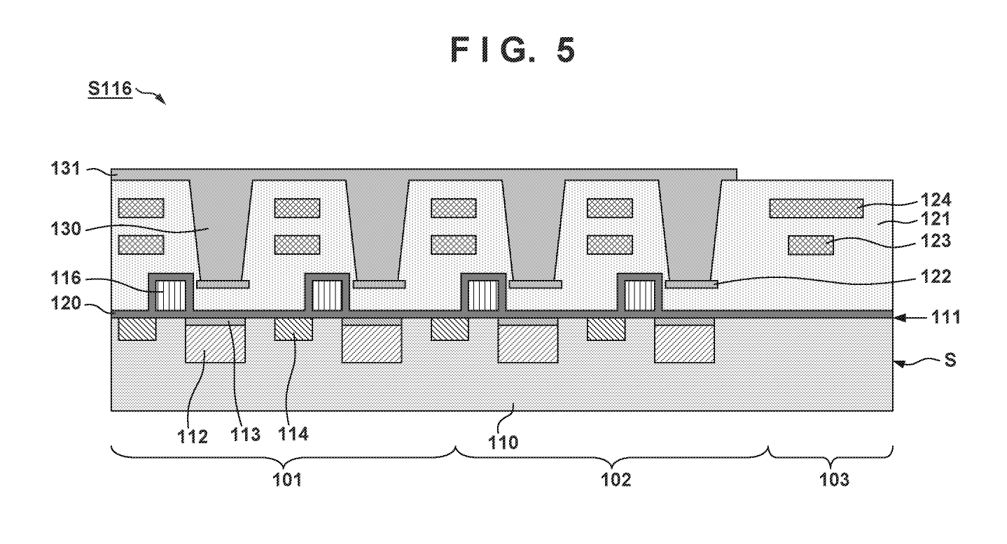

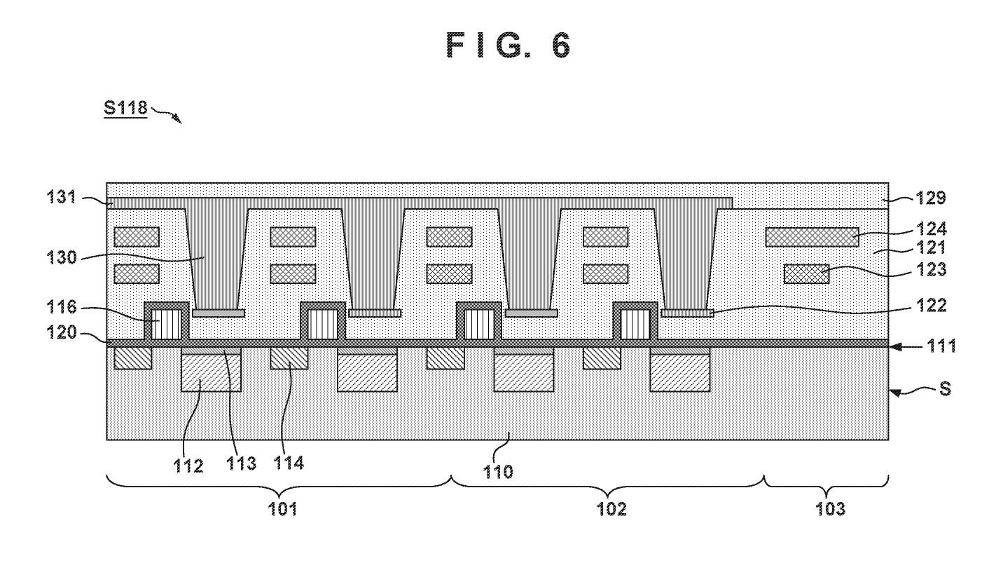

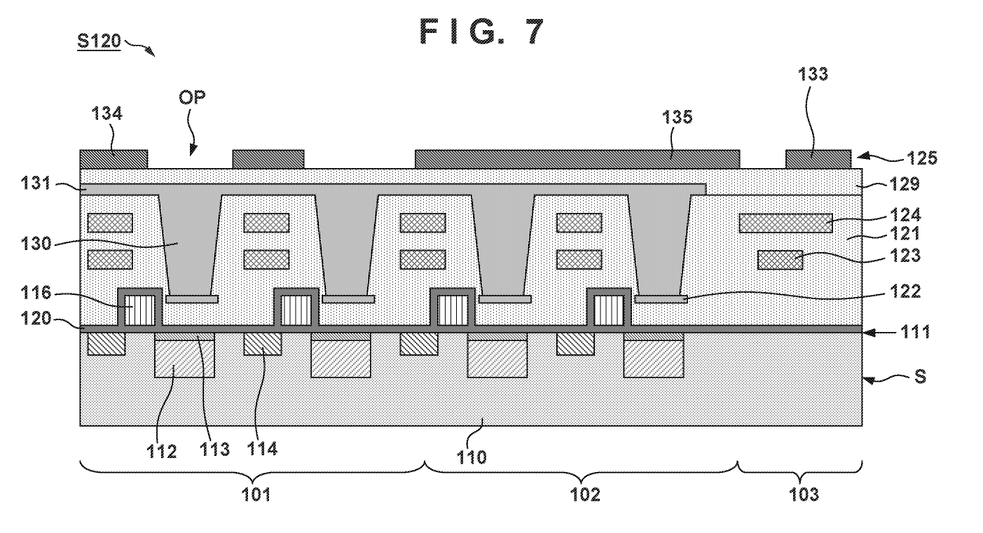

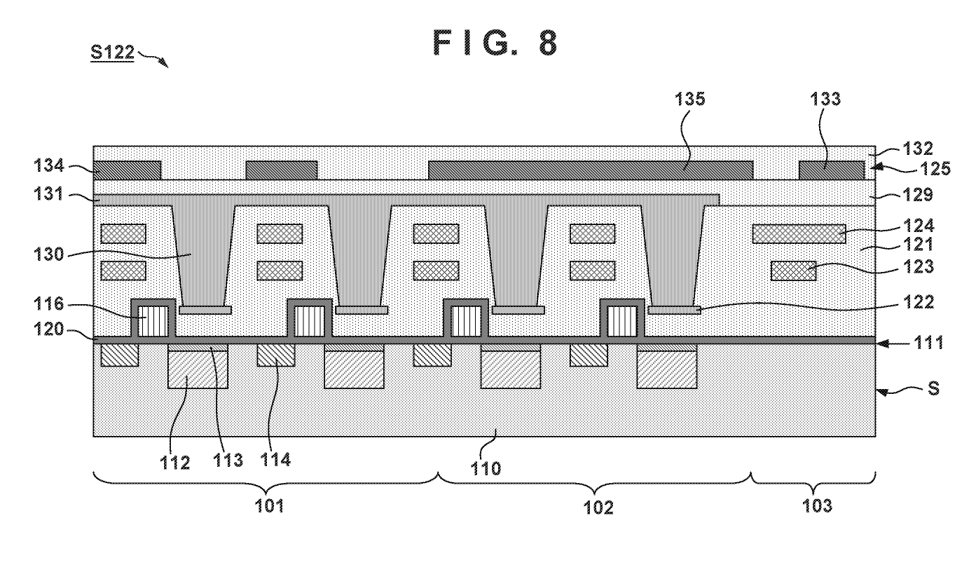

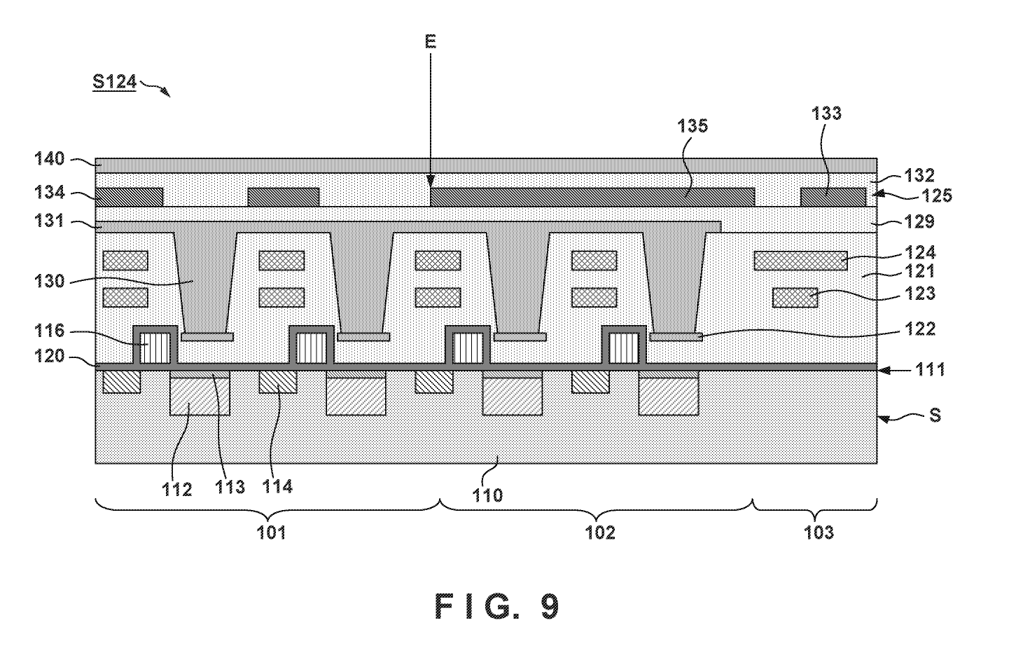

An example of a method of manufacturing the image capturing device 100 according to the first embodiment will be described below with reference to FIGS. 3, 4, 5, 6, 7, 8, and 9. In step S110, the semiconductor regions 112, 113, and 114 and the like are formed in the semiconductor layer 110 of the semiconductor substrate S. Each gate insulating film 119, each gate electrode 116, the insulating film 120, an etching stop film 122, and an insulating layer 121a are formed above the semiconductor substrate S. In this case, the insulating layer 121a is an insulating layer forming part of the interlayer insulating film 121.

As an example, each semiconductor region 112 (charge accumulation portion) is formed in the semiconductor layer 110, and the gate insulating film 119 and each gate electrode 116 can then be formed. After that, each semiconductor region 113 and each semiconductor region 114 can be formed. Subsequently, the insulating film 120 is formed above the semiconductor substrate S so as to cover the principal face 111 and each gate electrode 116. The insulating film 120 can be made of, for example, silicon nitride. Alternatively, the insulating film 120 may be formed from a multilayer film including the silicon nitride film and the silicon oxide film. The insulating film 120 can have a function of reducing damage to the photoelectric converters PEC in the subsequent step. The insulating film 120 may function as an antireflection film. After that, a film forming part of the insulating layer 121a can be formed, and the etching stop film 122 can be formed on this film. The etching stop film 122 can be made of, for example, silicon nitride. After that, a film forming another part of the insulating layer 121a is formed, and the upper face of this film is planarized by a method such as CMP, thereby forming the insulating layer 121a. Note that the insulating film 120 and the etching stop film 122 need not be formed.

In step S112, an insulating layer 121b, the electrically-conductive member of the first wiring layer 123, insulating layers 121c and 121d, the electrically-conductive member of the second wiring layer 124, and an insulating layer 121e are formed. The insulating layer 121b, 121c, 121d, and 121e are layers forming another part of the interlayer insulating film 121. First, the interlayer insulating film 121b is formed on the insulating layer 121a. The insulating film 121b can be formed such that an insulating material layer forming the insulating film 121b is formed, and a portion at which the electrically-conducive member of the first wiring layer 123 is to be arranged out of the insulating material layer is etched to form a groove. After that, a metal film is formed over the entire area of the light-receiving area 101, the light-shielded area 102, and the peripheral circuit area 103. The metal film is removed by a method such as CMP or the like until the upper surface of the insulating layer 121a is exposed, thereby forming the electrically-conductive material of the first wiring layer 123. Part of the electrically-conductive member of the first wiring layer 123 can be electrically connected to the semiconductor substrate S by a plug (not shown).

After that, the insulating layer 121c is formed over the entire area of the light-receiving area 101, the light-shielded area 102, and the peripheral circuit area 103. The insulating layer 121d can then be formed. The insulating layer 121d is formed from the insulating material layer forming the insulating layer 121d. Out of the insulating material layer, a portion at which the electrically-conductive member of the second wiring layer 124 is to be arranged is etched to form a groove. Out of the insulating layer 121c, a portion at which a plug for electrically connecting the electrically-conductive member of the first wiring layer 123 and the electrically-conductive member of the second wiring layer 124 is arranged is etched to form a via hole. After that, a metal film is formed in the entire area including the light-receiving area 101, the light-shielded area 102, and the peripheral circuit area 103, and the metal film is removed by a method such as CMP or the like until the upper face of the insulating film 121d is exposed, thereby forming the electrically-conductive member of the second wiring layer 124 together with the plug. Note that after the insulating layers 121c and 121d are formed, a portion corresponding to the area at which a plug for electrically connecting the electrically-conductive member of the first wiring layer 123 and the electrically-conductive member of the second wiring layer 124 is arranged is removed by etching.

After that, the insulating layer 121e is formed on the insulating layer 121d and the electrically-conductive member of the second wiring layer 124. Accordingly, the interlayer insulating film 121 formed from the insulating layer 121b, the insulating layers 121c and 121d, and the insulating layer 121e is obtained. The upper face of the insulating layer 121e may be planarized by a method such as CMP or the like, as needed. An etching stop film, a metal diffusion preventive film, or a layer having the functions of the etching stop film and the metal diffusion preventive film may be formed in the interlayer insulating film 121. More specifically, if the interlayer insulating film 121 is formed from a silicon oxide film, a silicon nitride film or a carbon-containing silicon oxide film may be employed as the etching stop film and the metal diffusion preventive film. Note that in the above example, the first wiring layer 123 and the second wiring layer 124 are formed by a damascene method. However, the first wiring layer 123 and the second wiring layer 124 may be formed by a method other than the damascene method.

In step S114, the plurality of holes H for forming the plurality of waveguides (the waveguide portions 130) are formed in the interlayer insulating film 121. The plurality of holes H can be formed such that an etching mask pattern having openings at portions at which the plurality of waveguides (the waveguide portions 130) are to be formed on the interlayer insulating film 121, and the interlayer insulating film 121 is etched through the openings. When the etching stop film 122 is formed, etching of the interlayer insulating film 121 is performed until the etching stop film 122 is exposed. As the etching condition for etching the interlayer insulating film 121, the etching stop film 122 can be made of a material by which the etching rate of the etching stop film 122 is lower than that of the interlayer insulating film 121. If the interlayer insulating film 121 is formed from a silicon oxide film, the etching stop film 122 can be made of silicon nitride or silicon oxynitride. In addition, the interlayer insulating film 121 may be etched by a plurality of etching operations having different conditions until the etching stop film 122 is exposed.

In step S116, the plurality of waveguide portions 130 respectively arranged in the plurality of holes H and the connecting portion 131 arranged on the interlayer insulating film 121 so as to connect the plurality of waveguide portions 130 are formed. First, a waveguide material layer made of a material for forming the waveguide portions 130 and the connecting portion 131 can be deposited in the entire area of the light-receiving area 101, the light-shielded area 102, and the peripheral circuit area 103. This deposition can be performed by, for example, a deposition method such as CVD or sputtering or coating of an organic material represented by a polyimide-based polymer. After that, by planarizing the waveguide material layer by a planarizing method such as an etch-back method or CMP method, the plurality of waveguide portions 130 and the connecting portion 131 can be formed. After that, the waveguide material layer in the peripheral circuit area 103 can be removed.

In step S114, if the interlayer insulating film 121 is etched until the etching stop film 122 is exposed, the waveguide portions 130 are arranged to contact the etching stop film 122. In the above example, although the waveguide material layer on the interlayer insulating film 121 in the peripheral circuit area 103 is removed, it may be left behind. By depositing the same material a plurality of times, the waveguide portions 130 and the connecting portion 131 may be formed. Alternatively, by sequentially deposing a plurality of different materials, the waveguide portions 130 and the connecting portion 131 may be formed. For example, by first depositing a silicon nitride film and then depositing an organic material having a high burying property, the waveguide portions 130 and the connecting portion 131 may be formed. The waveguide portions 130 and the connecting portion 131 can be made of a material having a refractive index higher than that of the interlayer insulating film 121. If the interlayer insulating film 121 is made of silicon oxide, the waveguide portions 130 and the connecting portion 131 can be made of silicon nitride. Silicon nitride has a refractive index of about 2.0, and the surrounding silicon oxide film has a refractive index of about 1.4. For this reason, based on the Snell's law, light is reflected at the interface between each waveguide portion 130 and the interlayer insulating film 121. Accordingly, light is confined in each waveguide portion 130.

In step S118, the interlayer insulating film 129 is formed to cover the plurality of waveguide portions 130 and the connecting portion 131. The interlayer insulating film 129 can be made of, for example, silicon oxide. After that, the interlayer insulating film 129 is planarized by a method such as CMP. By planarizing the interlayer insulating film 129, processing accuracy (patterning accuracy) of the light-shielding films 134 and 135 and the third wiring layer 125 including the electrically-conductive member 133, all of which will be formed later, can be improved. In the photolithography process for patterning the third wiring layer 125, the unevenness of the surface of a resist film arranged on the third wiring layer 125 can easily fall within the range of the depth of the projection optical system of an exposure apparatus.

In step S120, the light-shielding films 134 and 135 and the electrically-conductive member 133 are formed. These can be formed such that a metal film is formed above the interlayer insulating film 129, an etching mask pattern is formed on the metal film by a photolithography process, and the metal film is patterned through the openings of the etching mask pattern. The light-shielding films 134 and 135 and the electrically-conductive member 133 can be made of, for example, aluminum. The third wiring layer 125 can be electrically connected to the electrically-conductive member of the second wiring layer 124 by a plug (not shown). In addition, the light-shielding films 134 and 135 may be electrically connected to the electrically-conductive member 133 or to the electrically-conductive member of the second wiring layer 124 via a plug.

In step S122, the insulator film 132 is formed on the third wiring layer 125. The insulator film 132 can be made of silicon oxide. After that, the insulator film 132 can be planarized by a method such as CMP. In step S124, the light transmissive film 140 is formed on the insulator film 132. The light transmissive film 140 can be made of silicon nitride. If the upper face of the insulator film 132 is planarized, the lower face of the light transmissive film 140 is made flat in the light-receiving area 101 and the light-shielded area 102. Since the lower face of the light transmissive film 140 is made flat immediately above and near the end portion E of the light-shielding film 135 arranged in the light-shielded area 102, light is not deflected immediately above and near the end portion E. This makes it possible to suppress the incidence of light to the light-shielded area 102. Since the light transmissive film 140 is made flat immediately above and near the end portion of the light-shielding film 134 of the light-receiving area 101, the crosstalk between the pixels can be reduced due to the same reason as described above. The light transmissive film 140 can be formed from a silicon nitride film. The silicon nitride film is a film containing nitrogen and silicon or may additionally contain another element such as oxygen. In other words, the silicon nitride film can contain silicon oxynitride in addition to pure silicon nitride. The light transmissive film 140 may be formed from a multilayer film. The multilayer film can include, for example, a silicon nitride film and a silicon oxynitride film. This is advantageous in suppressing light reflection at the interface of the light transmissive film 140.

The illustration in the last step is substituted by the illustration in FIG. 2. In the step shown in FIG. 2, the organic material film 142, the color filter 143, and the microlenses 144 are formed. First, the organic material film 142 is formed on the light transmissive film 140. The organic material film 142 can be made of an insulator such as a polyimide-based organic material. After that, the color filter 143 and the microlenses 144 can be formed in an area corresponding to the photoelectric converters PEC.

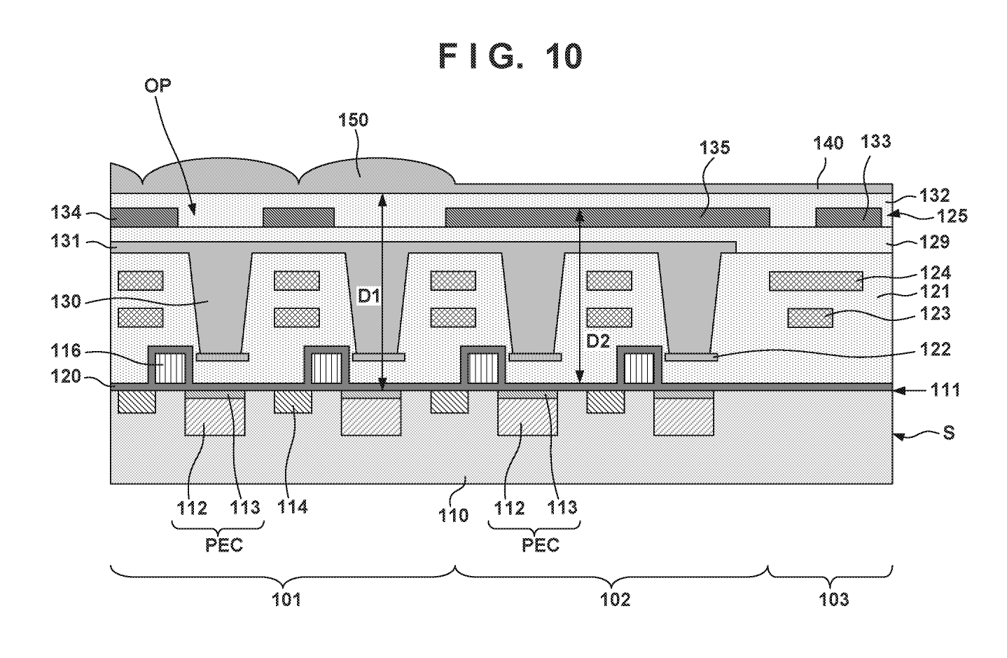

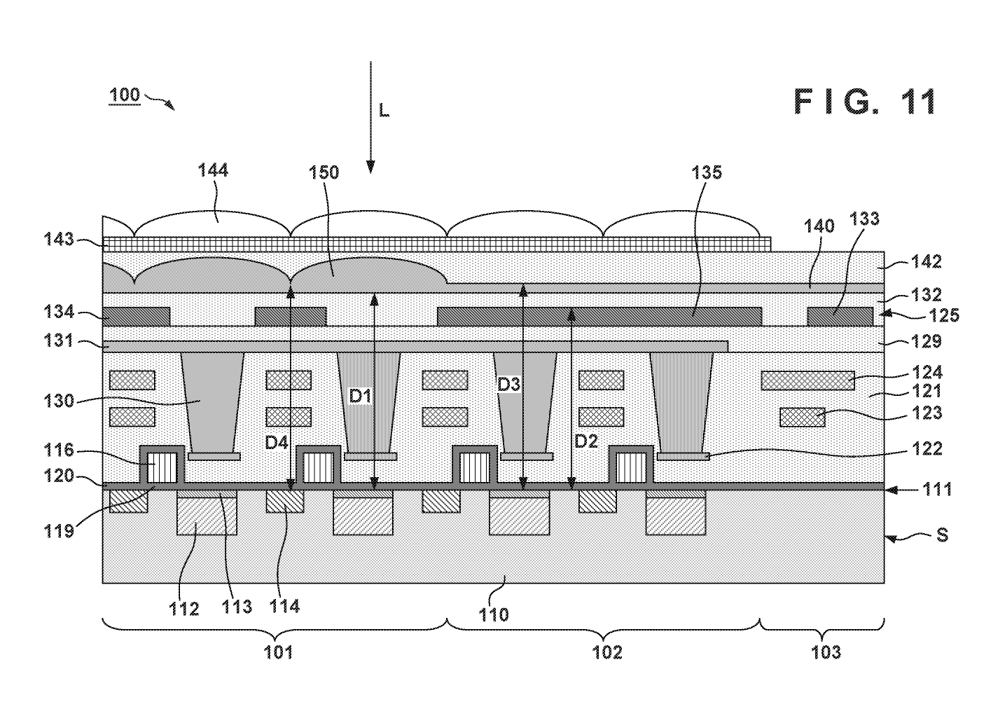

The arrangement of an image capturing device 100 according to the second embodiment of the present invention and a method of manufacturing the same will be exemplified below. Items which are not referred to as the second embodiment can comply with the first embodiment. In particular, the method of manufacturing the image capturing device 100 of the second embodiment can comply with steps S110, S112, S114, S118, S120, and S122 in the method of manufacturing the image capturing device 100 of the first embodiment. In place of step S124 of the first embodiment, the manufacturing method of the second embodiment includes a step exemplified in FIG. 10. In the step exemplified in FIG. 10, a light transmissive film 140 including interlayer lenses 150 arranged in a light-receiving area 101 is formed on an insulator film 132. The interlayer lenses 150 are arranged on openings OP of a light-shielding film 134 in the light-receiving area 101. Since the light transmissive film 140 is a film containing nitrogen and silicon, it can also be referred to as a silicon nitride film. The silicon nitride film can be, for example, a multilayer film including a silicon nitride film and a silicon oxide film.

In the step exemplified in FIG. 10, first, an insulating material layer for forming the light transmissive film 140 can be formed on the insulator film 132. After that, an etching mask pattern can be formed on the insulating material layer. The etching mask pattern can be formed such that, for example, after a photoresist pattern is formed by a photolithography process, the photoresist pattern is heated. By heating the photoresist pattern, the photoresist pattern can be deformed to have a lens surface shape. Each interlayer lens 150 preferably has an appropriate curvature in the area immediately above the light-shielding film 134, thereby suppressing light (light not entering each opening OP) entering the light-shielding film 134 and improving the sensitivity. As an example, a distance D3 between a principal face 111 and the upper face of the light transmissive film 140 in a light-shielded area 102 is equal to or smaller than a shortest distance D4 between the principal face 111 and the upper face of the light transmissive film 140 in the light-receiving area 101.

Next, in the step exemplified in FIG. 11, an organic material film 142, a color filter 143, and microlenses 144 can be formed. First, the organic material film 142 is formed on the light transmissive film 140. The organic material film 142 can be made of an insulator such as a polyimide-based organic material. After that, the color filter 143 and the microlenses 144 can be formed in an area corresponding to photoelectric converters PEC.

In the light-receiving area 101 and the light-shielded area 102, a distance D2 between the principal face 111 and the upper face of the light-shielding film 134 and a light-shielding film 135 is smaller than a distance D1 between the lower face of the light transmissive film 140 and the principal face 111 of a semiconductor substrate S. Therefore, the variations in outputs from the light-shielding pixels can be suppressed, and the crosstalk (for example, color mixing) between the pixels in the light-receiving area 101 can be reduced.

An electronic device such as a camera or smartphone or a transportation apparatus such as an automobile in which the image capturing device 100 is incorporated as an image sensing apparatus will be described as an application example of the image capturing device 100 of each of the above embodiments. In this case, the concept of the camera includes not only an apparatus of imaging as the main purpose but also an apparatus (for example, a personal computer and a portable terminal such as a tablet) having an auxiliary imaging function.

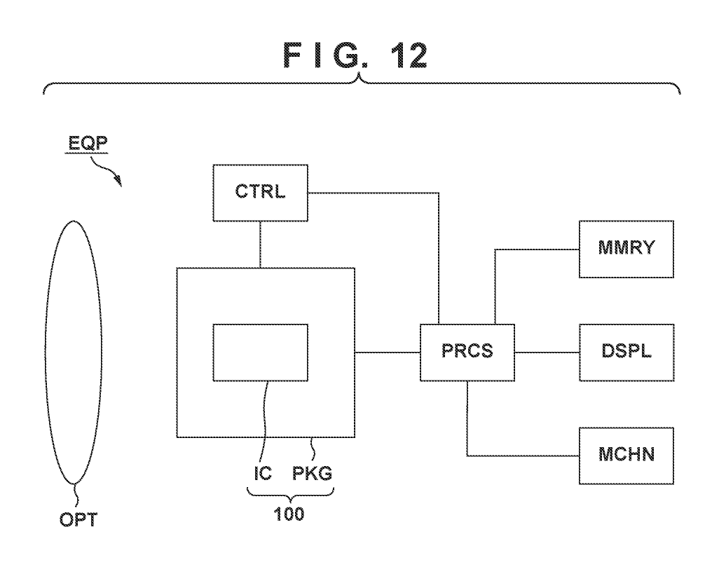

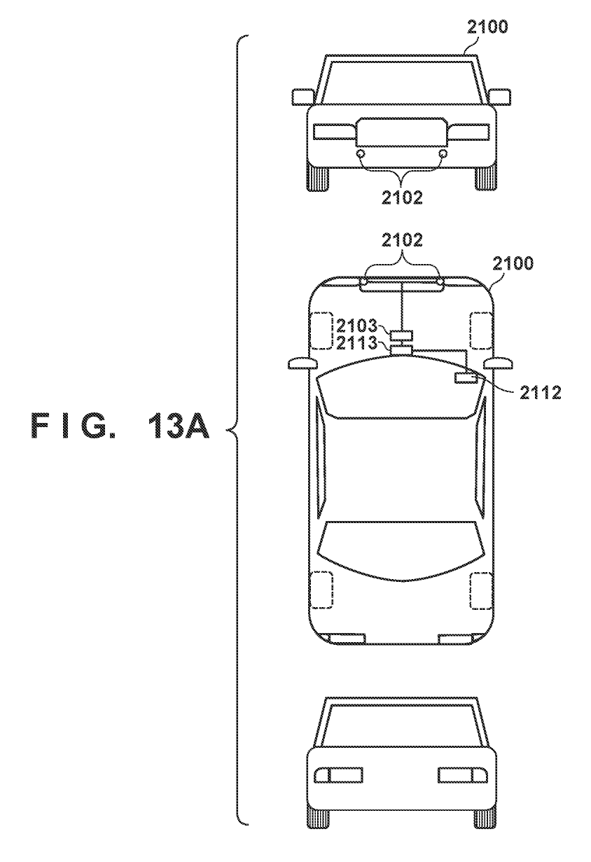

FIG. 12 is a schematic view of a device EQP incorporating the image capturing device 100. An example of the equipment EQP is an electronic device (information device) such as a camera or smartphone or a transportation apparatus such as an automobile or airplane. The image capturing device 100 can include a package PKG configured to store a semiconductor device IC in addition to the semiconductor device IC including a semiconductor substrate (semiconductor chip). The package PKG can include a base on which the semiconductor device IC is fixed, a lid made of glass facing the semiconductor device IC, and connection members such as bonding wires and bumps for connecting terminals of the base and the terminals of the semiconductor device IC. The device EQP further includes at least one of an optical system OPT, a controller CTRL, a processor PRCS, a display device DSPL, and a storage device MMRY. The optical system OPT is a system for forming an optical image on the image capturing device 100 and is made of, for example, a lens, a shutter, and a mirror. The controller CTRL controls an operation of the image capturing device 100 and is a semiconductor device such as an ASIC. The processor PRCS processes a signal output from the image capturing device 100 and is a semiconductor device such as a CPU or ASIC forming an AFE (Analog Front End) or a DFE (Digital Front End). The display device DSPL includes an EL display device or liquid crystal display device configured to display information (image) obtained by the image capturing device 100. The storage device MMRY is a magnetic device or semiconductor device configured to store information (image) obtained by the image capturing device 100. The storage device MMRY is a volatile memory such as an SRAM or DRAM or a nonvolatile memory such as a flash memory or hard disk drive. A machine apparatus MCHN includes a moving or propulsion mechanism such as a motor or engine. The machine apparatus MCHN in the camera can drive the components of the optical system OPT in order to perform zooming, an in-focus operation, and a shutter operation. The device EQP displays the signal output from the image capturing device 100 on the display device DSPL and performs external transmission by a communication device (not shown) of the device EQP. For this purpose, the device EQP may further include the storage device MMRY and the processor PRCS in addition to the memory circuits and arithmetic circuits included in the control/signal processing circuits in which the image capturing device 100 is incorporated.

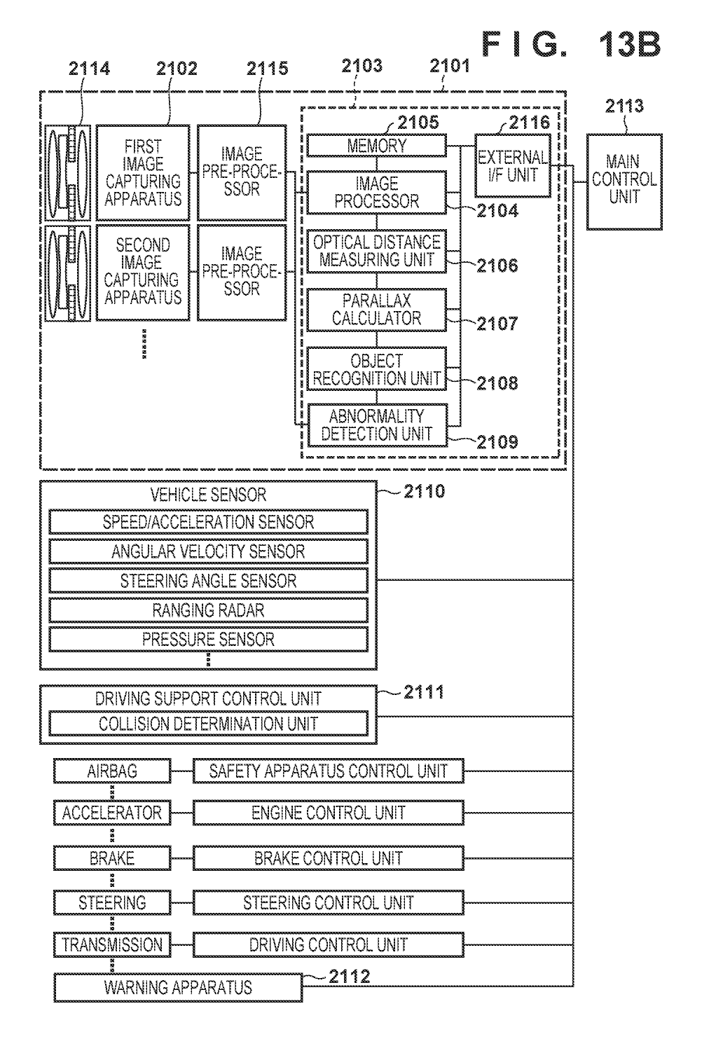

As described above, in the image capturing device 100 according to each of the first and second embodiments, the outputs from the light-shielding pixels can be stabilized, and the crosstalk between the pixels in the light-receiving area can be reduced. A camera in which the image capturing device 100 is incorporated is suitable as an onboard camera mounted in the transportation apparatus such as an automobile or railroad train. An example in which a camera incorporating the image capturing device 100 is applied to the transportation apparatus will be explained. A transportation apparatus 2100 is an automobile including an onboard camera 2101 shown in, for example, FIGS. 13A and 13B. FIG. 13A schematically shows the outer appearance and the main internal structure of the transportation device 2100. The transportation apparatus 2100 includes photoelectric conversion apparatuses 2102, an image sensing system integrated circuit (ASIC: Application Specific Integrated Circuit) 2103, an alarming device 2112, and a controller 2113.

The image capturing device 100 are used as the photoelectric conversion apparatuses 2102. Upon reception of an abnormality signal from an image sensing system, vehicle sensors, or the control unit, the alarming device 2112 outputs an alarm to a driver. The controller 2113 comprehensively controls the operations of the image sensing system, the vehicle sensors, and the control unit. Note that the transportation apparatus 2100 need not comprise the controller 2113. In this case, the image sensing system, the vehicle sensors, and the control unit have individual communication interfaces which exchange control signals via a communication network (for example, the CAN standard).

FIG. 13B is a block diagram showing the system arrangement of the transportation apparatus 2100. The transportation apparatus 2100 includes a first photoelectric conversion apparatus 2102 and a second photoelectric conversion apparatus 2102. That is, the onboard camera of this embodiment is a stereo camera. An object image is focused on each photoelectric conversion apparatus 2102 by an optical unit 2114. A pixel signal output from each photoelectric conversion apparatus 2102 is processed by an image preprocessor 2115 and is transmitted to the image sensing system integrated circuit 2103. The image preprocessor 2115 performs S-N calculation, sync signal addition, and the like. A signal processor 902 corresponds to at least part of the image preprocessor 2115 and the image sensing system integrated circuit 2103.

The image sensing system integrated circuit 2103 includes an image processor 2104, a memory 2105, an optical distance measurement unit 2106, a parallax calculation unit 2107, an object recognition unit 2108, an abnormality detection unit 2109, and an external interface (I/F) unit 2116. The image processor 2104 processes signals output from the respective pixels of each photoelectric conversion apparatus 2102 and generates an image signal. The image processor 2104 performs correction of the image signal and complementation of an abnormal pixel. The memory 2105 temporarily holds the image signal. In addition, the memory 2105 may store the position of the abnormal pixel of the known photoelectric conversion apparatus 2102. The optical distance measurement unit 2106 performs the in-focus operation and distance measurement of the object using the image signal. The parallax calculation unit 2107 performs object collation (stereo matching) of a parallax image. The object recognition unit 2108 analyzes the image signal and recognizes the object such as the transportation apparatus, a person, a sign, or a road. The abnormality detection unit 2109 detects the failure or operation error of each photoelectric conversion apparatus 2102. If the abnormality detection unit 2109 detects a failure or operation error, it sends a signal indicating that the abnormality is detected to the controller 2113. The external I/F unit 2116 interfaces information exchange between each unit of the image sensing system integrated circuit 2103 and the controller 2113 or various kinds of control units.

The transportation apparatus 2100 includes a vehicle information acquisition unit 2110 and a driving support unit 2111. The vehicle information acquisition unit 2110 includes vehicle sensors such as a speed/acceleration sensor, an angular velocity sensor, a steering sensor, a distance measuring radar, and a pressure sensor.

The driving support unit 2111 includes a collision determination unit. The collision determination unit determines based on information from the distance measurement unit 2106, the parallax calculation unit 2107, and the object recognition unit 2108 whether a collision with an object is possible. The optical distance measurement unit 2106 and the parallax calculation unit 2107 are examples of distance information acquisition means for acquiring distance information to the object. That is, the distance information is information about a parallax, a defocus amount, a distance to an object, and the like. The collision determination unit determines the collision possibility using any one of pieces of distance information. The distance information acquisition means may be implemented by dedicated design hardware or a software module.

An example in which the transportation apparatus 2100 is controlled by the driving support unit 2111 so as not to collide with another object has been described above. The present invention is also applicable to automated driving control for causing a self-vehicle to follow another vehicle and automated driving control in which the self-vehicle does not stray onto the next lane.

The transportation apparatus 2100 further includes driving apparatuses such as airbags, an accelerator pedal, a brake pedal, a steering wheel, a transmission, an engine, a motor, wheels, a propeller, and the like, which are used to move the vehicle or used to help the movement. Also, the transportation apparatus 2100 includes these control units. The control unit controls the corresponding driving apparatus based on a control signal from the controller 2113.

The applications of the image sensing system used in this embodiment are not limited to automobiles and railroad vehicles, but the image sensor system can be used for a transportation apparatus such as a ship, an airplane, or an industrial robot. In addition, the present invention is not limited to the transportation apparatus but is also applicable to an apparatus such as an ITS (Intelligence Transportation System) which uses broad object recognition.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-033678, filed Feb. 27, 2018, which is hereby incorporated by reference herein in its entirety.

What is claimed is:

1. An image capturing device having a light-receiving area and a light-shielded area, comprising:
a semiconductor substrate in which a plurality of photoelectric converters in the light-receiving area and the light-shielded area are arranged;
an insulating film arranged above a principal face of the semiconductor substrate and having a plurality of holes arranged above the plurality of photoelectric converters;
a plurality of waveguide portions arranged in the plurality of holes, respectively;
a connecting portion configured to connect the plurality of waveguide portions above the insulating film;
a light-shielding film arranged on the connecting portion in the light-receiving area and the light-shielded area and having an opening in the light-receiving area;
a silicon nitride film arranged on the light-shielding film in the light-receiving area and the light-shielded area so that the opening is arranged between the silicon nitride film and the semiconductor substrate in the light-receiving area; and
an insulator film having a portion located in the opening in the light-receiving area and having a portion located between the light-shielding film and the silicon nitride film in the light-receiving area and the light-shielded area,
wherein in the light-receiving area and the light-shielded area, a distance between an upper face of the light-shielding film and the principal face is smaller than a distance between a lower face of the silicon nitride film and the principal face.

2. The device according to claim 1, further comprising an insulating layer arranged between the plurality of waveguide portions and the light-shielding film.

3. The device according to claim 2, wherein an upper face of the insulating layer is flatter than a lower face of the insulating layer across an area including the light-receiving area and the light-shielded area, and the light-shielding film is arranged along the upper face of the insulating layer.

4. The device according to claim 1, wherein the insulator film is arranged so as to cover the light-shielding film, an upper face of the insulator film is flatter than a lower face of the insulator film, and the silicon nitride film is arranged along the upper face of the insulator film.

5. The device according to claim 4, wherein the upper face of the insulator film is spread across the light-receiving area and the light-shielded area.

6. The device according to claim 1, wherein the plurality of waveguide portions include a waveguide portion arranged between the light-shielding film and the photoelectric converter of the light-shielded area.

7. The device according to claim 1, wherein the connecting portion overlaps the light-shielding film in the light-shielded area.

8. The device according to claim 1, wherein an end portion of the light-shielding film on a side of the light-receiving area, which is located at a portion arranged in the light-shielded area overlaps at least one of the connecting portion and some of the plurality of waveguide portions.

9. The device according to claim 1, further comprising an organic material film arranged on the silicon nitride film.

10. The device according to claim 1, wherein a portion of the light-shielding film which is arranged in the light-receiving area is arranged at the same level as a portion of the light-shielding film which is arranged in the light-shielded area.

11. The device according to claim 10, wherein an electrode pad is arranged in the same layer as that of the light-shielding film.

12. The device according to claim 1, wherein the silicon nitride film forms an interlayer lens in the light-receiving area.

13. The device according to claim 12, wherein a distance between an upper surface of the silicon nitride film in the light-shielded area and the principal face is not more than a shortest distance between an upper face of the silicon nitride film of the light-receiving area and the principal face.

14. The device according to claim 1, further comprising a microlens arranged above the silicon nitride film.

15. An image capturing device having a light-receiving area and a light-shielded area, comprising:
a semiconductor substrate in which a plurality of photoelectric converters in the light-receiving area and the light-shielded area are arranged;
an insulating film arranged above a principal face of the semiconductor substrate and having a plurality of holes arranged above the plurality of photoelectric converters;
a plurality of waveguide portions arranged in the plurality of holes, respectively;
a light-shielding film arranged on the plurality of waveguide portions in the light-receiving area and the light-shielded area and having an opening in the light-receiving area;
a light transmissive film have an interlayer lens and arranged on the light-shielding film in the light-receiving area and the light-shielded area so that the opening is arranged between the light transmissive film and the semiconductor substrate in the light-receiving area; and
an insulator film having a portion located in the opening in the light-receiving area and having a portion located between the light-shielding film and the light transmissive film in the light-receiving area and the light-shielded area,
wherein in the light-receiving area and the light-shielded area, a distance between an upper face of the light-shielding film and the principal face is smaller than a distance between a lower face of the light transmissive film and the principal face.

16. The device according to claim 15, further comprising a connecting portion configured to connect the plurality of waveguide portions on the insulating film.

17. The device according to claim 16, wherein an end portion of the light-shielding film on a side of the light-receiving area in a portion arranged in the light-shielded area overlaps at least one of the connecting portion and some of the plurality of waveguide portions.

18. The device according to claim 15, further comprising an organic material film arranged on the light transmissive film.

19. The device according to claim 15, wherein a portion of the light-shielding film which is arranged in the light-receiving area is arranged at the same level as a portion of the light-shielding film which is arranged in the light-shielded area.

20. The device according to claim 15, wherein the light-shielding film includes a portion overlapping the interlayer lens.

21. An apparatus comprising:
an image capturing device defined in claim 1; and
a processing unit configured to process a signal output from the image capturing device.

22. An apparatus comprising a driving device, wherein the apparatus incorporates an image capturing device defined in claim 15, and the apparatus comprises a control device configured to control the driving device based on information obtained by the image capturing device.
